(19) United States
(12) Patent Application Publication
(10) Pub. No.: US 2002/0115289 A1
(43) Pub. Date: Aug. 22, 2002

(54) METHOD FOR DECREASING THE RESISTIVITY OF THE GATE AND THE LEAKY JUNCTION OF THE SOURCE/DRAIN

(76) Inventor: Bing-Chang Wu, Shu-Lin Chen (TW)

Correspondence Address: POWELL, GOLDSTEIN, FRAZER & MURPHY LLP, P.O. BOX 97223, WASHINGTON, DC, 20090-7223, US

(21) Appl. No.: 09/790,164

(22) Filed: Feb. 21, 2001

(51) Int. Cl. H01L 21/3205; H01L 21/4763; H01L 21/44

(52) U.S. Cl. 438/664; 438/683; 438/592

(57) ABSTRACT

This invention relates to a method for decreasing the resistivity of the gate and leaky junction of the source/drain, more particularly, to the method for forming a metal silicide layer at the gate region and the source/drain region by using the first poly layer which is pre-formed on the substrate to decrease the resistivity of the gate and to decrease defects in leaky junction at the source/drain region at the same time. In the present invention, the first poly layer and a oxide layer are formed on the substrate at first. After defining the place of the gate region and the source/drain region, a trench is etched at the place of the gate region and the first poly layer is showed at the bottom of the trench. The first poly layer which is at the bottom of the trench is removed and the spacers are formed on the sidewalls of the trench. Then a gate oxide layer and the second poly layer are formed at the bottom of the trench and the second poly layer is filled of the trench. After polishing the over deposition second poly layer and removing the oxide layer, the gate is formed on the substrate. After forming a metal layer on the substrate and passing through two times of rapid thermal process steps, a metal silicide layers are formed at the gate region and the source/drain region and finish the salicide process.

### BACKGROUND OF THE INVENTION

1. Field of the Invention

This invention relates to a method for decreasing the resistivity of the gate and leaky junction of the source/drain, more particularly, to the method for forming a metal silicide layer at the gate region and the source/drain region by using the first poly layer which is pre-formed on the substrate to decrease the resistivity of the gate and to decrease defects in leaky junction at the source/drain region at the same time.

2. Description of the Prior Art

An increment in device integrity makes the resistance of metal oxide semiconductor (MOS) device source/drain regions gradually climb up and almost equal to the resistance of MOS device channel. In order to reduce the sheet resistance of source/drain regions and to guarantee a complete shallow junction between metal and MOS device, the application of a “Self aligned Silicide” process is gradually steeping into the very large scale integration (VLSI) fabrication of 0.5 micron (μm) and below. This particular process is called “Salicide” for short.

In general, the titanium silicon is usually used in silicide. The titanium silicide is formed to use two sequence steps rapid thermal process. At first, referring to FIG. 1, a silicon substrate 10 is provided and a MOS device and a shallow trench isolation are formed thereon. The MOS device comprises a source/drain region 12 a gate region, and as well as a spacer 18 formed on the sidewalls of the gate region. This gate region comprises a gate oxide layer 14 and a polysilicon layer 16, then using the chemical vapor deposition technique or the magnetron direct current sputtering technique to deposit a titanium metal layer 20 over the MOS and the shallow trench isolation. The thickness of the titanium metal layer 20 is about more than 300 angstroms. Next, a rapid thermal process is performed, wherein part of the titanium metal layer will react with the silicon on the source/drain region and with the polysilicon of the gate region to form a titanium silicide layer. The thickness of this titanium silicide layer is about 600 to 700 angstroms. The structure of this titanium silicide layer is a metastable C-49 phase structure with higher resistivity. Referring to FIG. 2, the unreacted titanium metal and the remained titanium metal are removed by applying the RCA cleaning method. Therefore, the titanium silicide layer 22 is existed on top of the gate region and the source/drain region. Finally, a rapid thermal process is performed again to transform higher resistivity of the C-49 phase titanium silicide structure into lower resistivity of the C-54 phase titanium silicide structure.

In the deep sub-micron device fabrication, the decline of the device driving current that cause by parasitic seties resistance of source/drain can be avoided by siliciding the source/drain. The above can be accomplished by either using simple silicidation of source/drain or self-aligned silicidation, where self-aligned silicidation can accomplish the silicidations of source/drain and gate region at the same time.

However, in accompanying with the shrinkage of the devices, the conventional method of depositing titanium metal to a thickness greater than about 300 angstroms, and as well as using rapid thermal process for forming titanium silicide, thicker silicon substrate is consumed at the source/drain region. Therefore, results in shallower junctions. In order to avoid the formation of leaky junctions, the thickness of the silicide layer at the source/drain region must be thinner enough as devices to be shrinked in size. If the thinner titanium metal layer is formed over the MOS and is passed through two times of the rapid thermal process, the produced titanium silicide layer is thinner at the source/drain region. But titanium silicide layer is following thinner at the gate region to cause higher resistivity of the gate. Therefore, the present invention is must used to pre-from the first poly layer to react with the metal layer to form the metal silicide layer at the source/drain region. This condition will not make the metal react with the silicon layer which is at the source/drain region to cause the defects in leaky junction at the source/drain region.

### SUMMARY OF THE INVENTION

In accordance with the above-mentioned invention backgrounds, the traditional method can not decrease the resistivity of the gate and the defects in leaky junction at the source/drain region at the same time by the thickness of the metal silicide layers which are formed at the gate region and the source/drain region. The present invention provides a method to use the pre-formed first poly layer which is on the substrate to form the metal silicide layer at the source/drain region to decrease the resistivity of the gate and the defects in leaky junction at the source/drain region at the same time.

The second objective of this invention is to increase the qualities of the semiconductor elements by using the pre-formed first poly layer which is on the substrate to form the metal silicide layer at the source/drain region.

The third objective of this invention is to decrease the width of the contact window by pre-forming the spacer and then forming the gate.

The fourth objective of this invention is to decrease the volume of the semiconductor element successfully by pre-forming the spacer and then forming the gate.

It is a further objective of this invention to increase the integrity of the element on the semiconductor by pre-forming the spacer and then forming the gate.

In according to the foregoing objectives, the present invention provides a method to decrease the width of the contact window and to decrease the volume of the semiconductor element to increase the integrity of the element on the semiconductor by pre-forming the spacers and then forming the gate. In the following salicide process, the present invention is also used to form the metal silicide layer at the source/drain region by using the pre-formed first poly layer which is on the substrate to make the metal silicide layer not react with the substrate to cause the defects in leaky junction. The present invention is further used to make thicker metal silicide layer at the gate region to decrease the resistivity of the gate.

### BRIEF DESCRIPTION OF THE DRAWINGS

In the accompanying drawing forming a material part of this description, there is shown:

FIG. 1 shows a diagram in forming a titanium layer over the MOS by using the traditional technology;

FIG. 2 shows a diagram in forming a titanium silicide layers on the gate region and source/drain region by using the traditional technology;

FIG. 3 shows a diagram in forming the first poly layer and a oxide layer on the substrate;

FIG. 4 shows a diagram in forming a trench in the oxide layer;

FIG. 5 shows a diagram in removing the first poly layer from the bottom of the trench and forming the spacers on the sidewalls of the trench;

FIG. 6 shows a diagram in forming a gate oxide layer at the bottom of the trench and forming the second poly layer in the trench;

FIG. 7 shows a diagram in forming a gate on the substrate;

FIG. 8 shows a diagram in removing the first poly layer which is at the inactive region;

FIG. 9 shows a diagram in forming the metal layer on the shallow trench isolation layer, the first poly layer, and the second poly layer; and

FIG. 10 shows a diagram in forming the metal silicide layer at the gate region and the source/drain region.

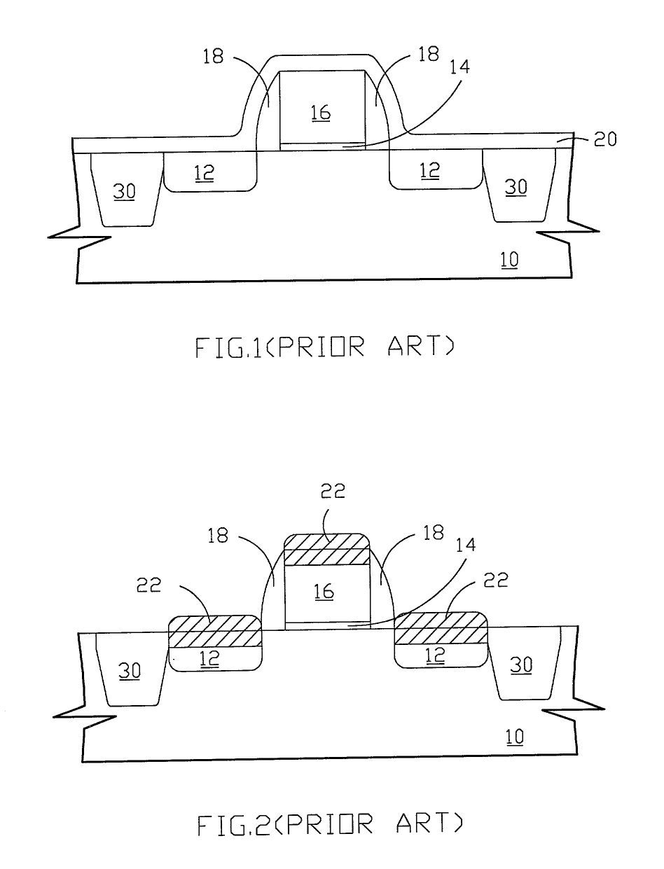

### DESCRIPTION OF THE PREFERRED EMBODIMENT

The foregoing aspects and many of the attendant advantages of this invention will become more readily appreciated as the same becomes better understood by reference to the following detailed description, when taken in conjunction with the accompanying drawings, wherein:

In the traditional salicide process, only a metal layer is formed on the MOS and the metal silicide layers are formed at the gate region and the source/drain region at the same time. Therefore, the thickness of the metal silicide layer which is formed at the gate region and the thickness of the metal silicide layer which is formed at the source/drain region are the same. When the volume of the semiconductor element is smaller and smaller or the width of the process is less than 0.1 microns, the traditional salicide process can not decrease the resistivity of the gate and decrease the defects in leaky junction at the source/drain region at the same time. The present invention is must used to decrease the volume of the semiconductor element successfully and to increase the qualities of the semiconductor element.

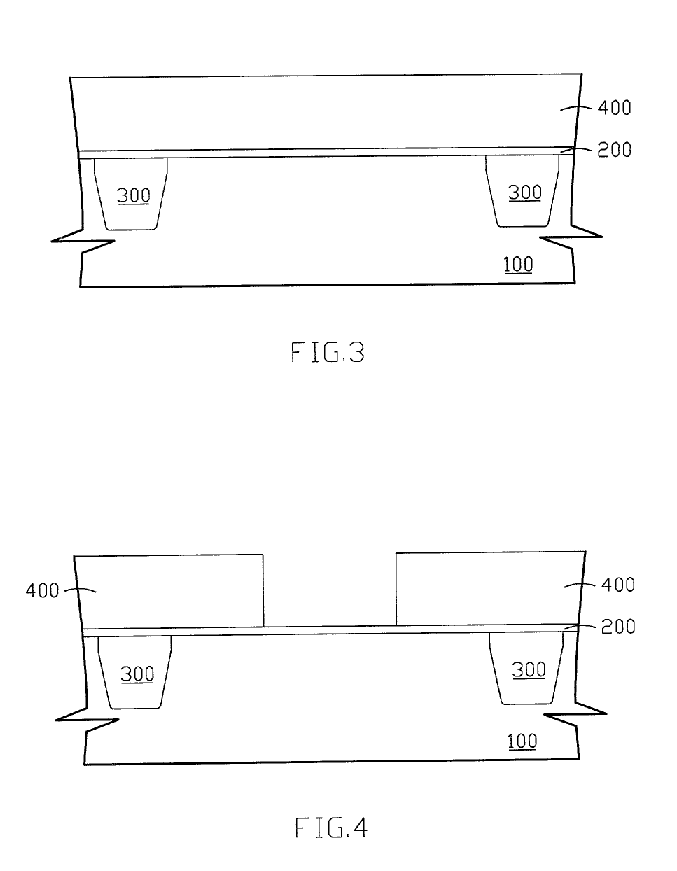

Referring to FIG. 3, a wafer wherein a substrate 100 is formed is provided. The substrate 100 can be a silicon substrate and the shallow trench isolation layers 300 are formed in the substrate 100. At first, the first poly layer 200 is formed on the substrate 100 and a oxide layer 400 is formed on the poly layer 200. The material of the first poly layer 200 is most a polysilicon material and the thickness of the poly layer is about 50 to 100 angstroms. The thickness of the oxide layer 400 is following the changes of the thickness of the needed gate.

Then defining the place of the gate region and forming a mask on the oxide layer 400 except the gate region. After passing through the etching process, the oxide layer 400 which is at the gate region is removed to show the first poly layer 200, the trench is formed in the oxide layer 400 and the mask is removed by using the chemical solutions according to FIG. 4.

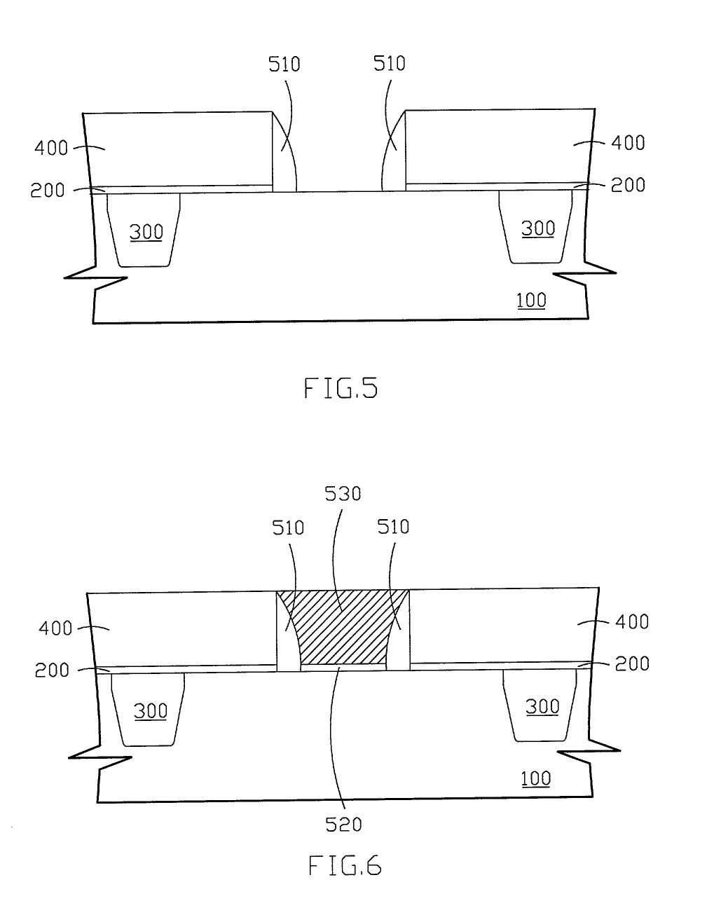

Referring to FIG. 5, after forming the trench in the oxide layer 400, the first poly layer 200 which is at the bottom of the trench is must removed to show the substrate 100. Then the material of the spacers 510 is filled the trench. After passing through an anisotropic etching process, the spacers 510 are formed on the sidewalls of the trench. The silicon dioxide is usually used to be a material of the spacers 510. After forming the spacers on the sidewalls of the trench, a gate oxide layer 520 is formed at the bottom of the trench. Then the second poly layer 530 is formed on the gate oxide layer and is filled of the trench. The polysilicon is most used to be the material of the second poly layer. Afterward the over deposition second poly layer 530 is removed by using the chemical mechanical polishing (CMP) process according to FIG. 6.

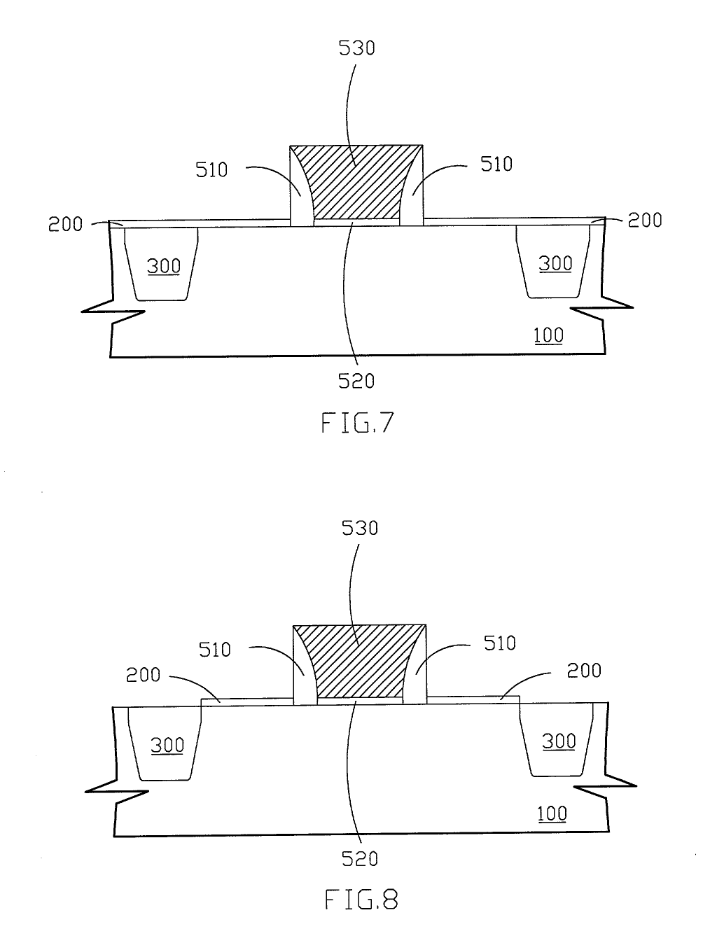

Referring to FIG. 7, after removing the oxide layer 400, the gate which comprises spacers 510, the gate oxide layer 520, and the second poly layer 530 is formed on the substrate 100. Then the salicide process is proceeded. Referring to FIG. 8, the first poly layer 200 which is on the inactive region is removed at first to retain the first poly layer 200 which is at the source/drain region.

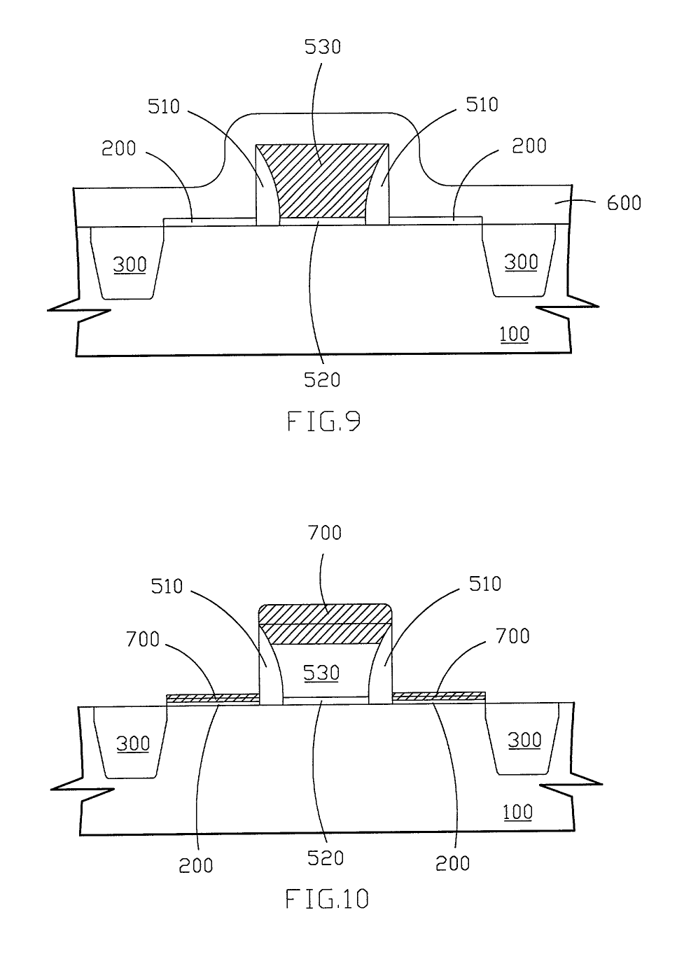

Referring to FIG. 9, a metal layer 600 is formed on the shallow trench isolation layer 300, the first poly layer 200, and the second poly layer 500. The thickness of the metal layer 600 is about 300 to 600 angstroms. The chemical vapor deposition method and the direct current magnetron sputtering method is most used to form the metal layer 600. Then the wafer is placed into the chamber to proceed the first rapid thermal process (RTP). The metal layer 600 will react with the silicon layer which is at the contact region to form the metal silicide layer. The using temperature of the forming metal silicide layer process is about 500 to 700° C. The structure of the metal silicide which is formed in the first rapid thermal process is a metastable C-49 phase structure with higher resistivity. Referring to FIG. 10, the unreacted and the remained first metal layer 600 is removed by applying the RCA cleaning method. Therefore, the metal silicide layers 700 are existed on the top of the gate region and the source/drain region. Finally, the second rapid thermal process is performed to transform higher resistivity of the C-49 phase metal silicide structure into lower resistivity of the C-54 phase metal silicide structure. The using temperature of the second rapid thermal process is about 750 to 850° C. The material of the metal layer 600 can be titanium, cobalt, and platinum. Titanium is usually used to be the material of the metal layer 600.

Titanium is the most common used metallic material for the current salicide process. Basically, titanium is a fine oxygen gettering material, where under an appropriate temperature titanium and silicon at MOS device source/drain and gate regions are easily mutually diffused to form a titanium silicide with very low resistance.

When proceeding the first rapid thermal process, the metal layer 600 will react with the first poly layer and the second poly layer to form the metal silicide layer 700. The substrate 100 which is under the source/drain region is prevented by the first poly layer 200 not to react with the metal layer 600 to form the over thickness metal silicide layer 70 to cause the defects in leaky junction at the source/drain region. Therefore, the thickness of the metal layer 600 is decided following the thickness of the metal silicide layer which is at the gate region. The thickness of the metal layer is about 300 to 600 angstroms to decrease the resistivity of the gate.

In accordance with the present invention, the present invention provides a method for decreasing the width of the contact window and decreasing the volume of the semiconductor element to increase the integrity of the elements on the semiconductor by pre-forming the spacers and then forming the gate. In the following salicide process, the present invention is also used to form the metal silicide layer at the source/drain region by using the pre-formed first poly layer which is on the substrate to make the metal silicide layer not react with the substrate to cause the defects in leaky junction. Therefore, the thickness of the metal layer is increased following the needed thickness of the metal silicide layer which is at the gate region. This condition can can further form thicker metal silicide layer at the gate region to decrease the resistivity of the gate.

Although specific embodiments have been illustrated and described, it will be obvious to those skilled in the art that various modifications may be made without departing from what is intended to be limited solely by the appended claims.

What is claimed is:

1. A method for forming a salicide, said method comprises:
providing a wafer, said wafer comprises a substrate;
forming a first poly layer on said substrate;
forming a oxide layer on said first poly layer;
removing part of said oxide layer to form a trench in said oxide layer and showing said first poly layer at a bottom of said trench;
removing said first poly layer of said bottom to show said substrate;
forming a spacer on a sidewall of said trench;
forming a gate oxide layer on said substrate of said bottom of said trench;
forming a second poly layer on said gate oxide layer and filling of said trench;
removing said oxide layer;
removing part of said first poly layer;
forming a metal layer on said second poly layer and said first poly layer;
proceeding a first rapid thermal process to form a metal silicide layer on said second poly layer and said first poly layer;
removing said metal layer; and
proceeding a second rapid thermal process.

2. The method according to claim 1, wherein said a material of said metal layer is titanium.

3. The method according to claim 1, wherein said a material of said metal layer is cobalt.

4. The method according to claim 1, wherein said a material of said metal layer is platinum.

5. The method according to claim 1, wherein said a material of said first poly layer is a polysilicon.

6. The method according to claim 1, wherein said a material of said second poly layer is a polysilicon.

7. The method according to claim 1, wherein said a material of said spacer is a silicon dioxide.

8. A method for forming a salicide, said method comprises:
providing a wafer, said wafer comprises a substrate, said substrate comprises a shallow trench isolation layer;
forming a first poly layer on said substrate;
forming a oxide layer on said first poly layer;
forming a mask on part of said oxide layer
removing part of said oxide layer to form a trench in said oxide layer and showing said first poly layer at a bottom of said trench;
removing said mask;
removing said first poly layer of said bottom to show said substrate;
forming a spacer on a sidewall of said trench;
forming a gate oxide layer on said substrate of said bottom of said trench;
forming a second poly layer on said gate oxide layer and filling of said trench;
removing said oxide layer;
removing part of said first poly layer;
forming a metal layer on said shallow trench isolation layer, said second poly layer, and said first poly layer;
proceeding a first rapid thermal process to form a metal silicide layer on said second poly layer and said first poly layer;
removing said metal layer; and
proceeding a second rapid thermal process.

9. The method according to claim 8, wherein said a material of said metal layer is titanium.

10. The method according to claim 8, wherein said a material of said metal layer is cobalt.

11. The method according to claim 8, wherein said a material of said metal layer is platinum.

12. The method according to claim 8, wherein said a material of said first poly layer is a polysilicon.

13. The method according to claim 8, wherein said a material of said second poly layer is a polysilicon.

14. The method according to claim 8, wherein said a material of said plural spacers is a silicon dioxide.

15. The method according to claim 8, wherein said a thickness of said first poly layer is about 50 to 100 angstroms.

16. The method according to claim 8, wherein said a temperature of said first rapid thermal process is about 500 to 700° C.

17. The method according to claim 8, wherein said a temperature of said second rapid thermal process is about 750 to 850° C.
